(19) United States
(12) Patent Application Publication
(10) Pub. No.: US 2014/0071625 A1
(43) Pub. Date: Mar. 13, 2014

(54) IMMERSION COOLING SYSTEM AND METHOD

(71) Applicant: Huawei Technologies Co., Ltd., Shenzhen (CN)

(72) Inventors: Zhaoxia Luo, Shenzhen (CN); Shuliang Huang, Shenzhen (CN); Youhe Ke, Shenzhen (CN); Liqian Zhai, Shenzhen (CN)

(73) Assignee: Huawei Technologies Co., Ltd., Shenzhen (CN)

(21) Appl. No.: 14/081,654

(22) Filed: Nov. 15, 2013

Related U.S. Application Data
(63) Continuation of application No. PCT/CN2011/080121, filed on Sep. 23, 2011.

(51) Int. Cl. H05K 7/20

(52) U.S. Cl. CPC H05K 7/20236
USPC 361/699

(57) ABSTRACT

Embodiments of the present invention provide an immersion cooling system, including: an electronic device, a non-conductive working medium, and one or more gasbags. The electronic device is immersed in the non-conductive working medium; the non-conductive working medium is configured to dissipate heat for the electronic device, and a volume of the non-conductive working medium expands as a temperature rises; and a surface of the gasbag is elastic, and the gasbag is configured to reduce its volume when the gasbag is compressed by volume expansion of the non-conductive working medium, so as to buffer a pressure rise in the system, where the pressure rise is caused by the volume expansion of the non-conductive working medium. With the immersion cooling system provided in the embodiments of the present invention, installation is more flexible and cooling performance of the system is further improved.

### CROSS-REFERENCE TO RELATED APPLICATIONS

This application is a continuation of International Application No. PCT/CN2011/080121, filed on Sep. 23, 2011, which is hereby incorporated by reference in its entirety.

### TECHNICAL FIELD

The present invention relates to the field of information and communications, and in particular, to an immersion cooling system and method.

### BACKGROUND

With rapid development of the information and communications industry, the integration level and heat density of a device become higher and higher. With increasing power consumption of a chip and a higher integration level of a device, a conventional technology that uses air as a medium to dissipate heat for an electronic product is increasingly not enough to meet requirements. The industry starts to seek a higher-density heat dissipation solution, and immersion cooling comes into people's view.

Immersion cooling refers to immersing a heat source in a non-conductive liquid to dissipate heat and control the temperature within a reasonable range. Compared with a conventional air cooling technology, immersion heat dissipation can deal with much higher heat density. Meanwhile, a system solution that adopts immersion heat dissipation is relatively simple, generally involves fewer components, and has higher reliability. However, after heat generated by a heat source immersed in a non-conductive working medium is absorbed by the non-conductive working medium, a temperature of the non-conductive working medium increases and a volume of the non-conductive working medium expands. Therefore, when an immersion heat dissipation solution is adopted, volume expansion of a working medium must be considered to prevent a safety problem caused by damage to a case due to the volume expansion.

To control a pressure rise caused by volume expansion of a non-conductive working medium in an immersion cooling system, most existing immersion cooling solutions in the industry adopt a manner of installing an exhaust valve. In the prior art, a specialized exhaust valve is set to prevent a pressure from rising or even causing a safety problem. A non-conductive working medium is contained in a case made of a solid material. By adopting this exhaust valve solution, a certain space is generally reserved at the time of filling a fluid working medium, that is, the non-conductive working medium occupies only a part of a space enclosed by the case, and the remaining space still contains gas. When a temperature of the non-conductive working medium rises and a volume of the non-conductive working medium expands, the non-conductive working medium starts to extrude the gas; and when a pressure of the gas rises to some extent, an exhaust pressure relief valve installed on a surface of the case starts to work and expels a part of the gas to the outside to reduce a pressure in the case.

An existing exhaust pressure relief valve in the industry generally has a large size and generally needs to be installed at a high position in a system. Therefore, its installation manner is limited to some extent. In addition, for an electronic device part that is not immersed in the non-conductive working medium but exposed in the gas, its heat dissipation capability is greatly affected. Especially for a board-level immersion system applied to a horizontal insertion frame, existence of an air layer seriously deteriorates heat transfer between a non-conductive working medium and a cold source case, thereby deteriorating heat dissipation performance of the entire system.

### SUMMARY

Embodiments of the present invention provide an immersion cooling system and method.

An embodiment of the present invention provides an immersion cooling system, where the system includes: an electronic device, a non-conductive working medium, and one or more gasbags, where the electronic device is immersed in the non-conductive working medium; the non-conductive working medium is configured to dissipate heat for the electronic device, and a volume of the non-conductive working medium expands as a temperature rises; and a surface of the gasbag is elastic, and the gasbag is configured to reduce its volume when the gasbag is compressed by volume expansion of the non-conductive working medium, so as to buffer a pressure rise in the system, where the pressure rise is caused by the volume expansion of the non-conductive working medium.

An embodiment of the present invention provides an immersion cooling method, where the method includes: dissipating heat for an electronic device by using a non-conductive working medium in a closed container, where the electronic device is immersed in the non-conductive working medium, and placing one or more elastic gasbags in the non-conductive working medium; and reducing, by the gasbag, its volume when the gasbag is compressed by volume expansion of the non-conductive working medium, so as to buffer a pressure rise in a system, where the pressure rise is caused by the volume expansion of the non-conductive working medium.

With the immersion cooling system and method provided in the embodiments of the present invention, a gasbag is used in place of an exhaust valve, so that installation is more flexible and cooling performance is further improved.

### BRIEF DESCRIPTION OF DRAWINGS

To describe the technical solutions in the embodiments of the present invention or in the prior art more clearly, the following briefly introduces the accompanying drawings required for describing the embodiments. Apparently, the accompanying drawings in the following description merely show some embodiments of the present invention, and persons of ordinary skill in the art may also derive other drawings from these accompanying drawings without creative efforts.

FIG. 1 is a structural diagram of an immersion cooling system according to an embodiment of the present invention;

FIG. 2 is a schematic diagram of a gasbag with only part of movable surfaces according to an embodiment of the present invention; and

FIG. 3 is a flowchart of an immersion cooling method according to an embodiment of the present invention.

### DESCRIPTION OF EMBODIMENTS

To make the objectives, technical solutions, and advantages of the embodiments of the present invention more comprehensible, the following clearly describes the technical solutions in the embodiments of the present invention with reference to the accompanying drawings in the embodiments of the present invention. Apparently, the embodiments to be described are merely a part rather than all of the embodiments of the present invention. All other embodiments obtained by persons of ordinary skill in the art based on the embodiments of the present invention without creative efforts shall fall within the protection scope of the present invention.

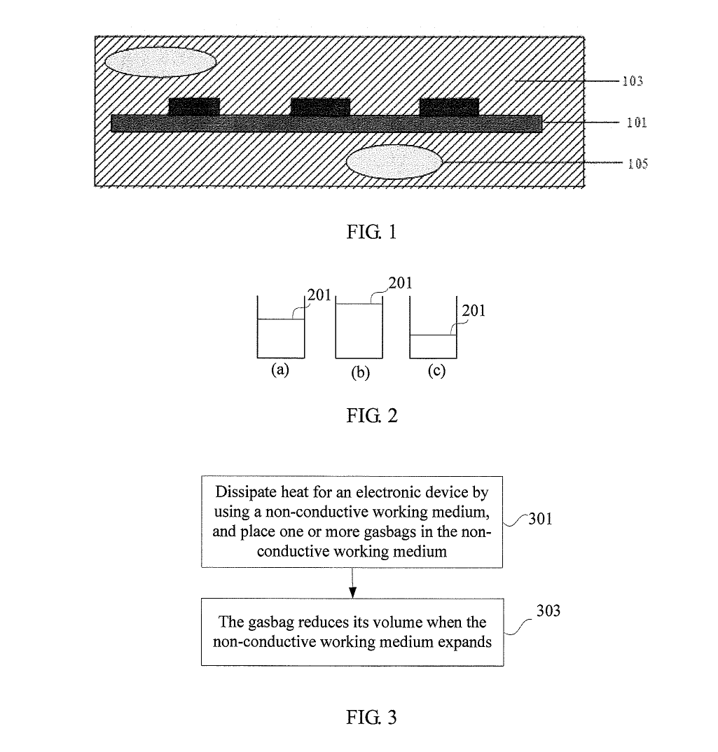

An embodiment of the present invention provides an immersion cooling system. Referring to FIG. 1, FIG. 1 is a structural diagram of an immersion cooling system according to an embodiment of the present invention. The system includes: an electronic device 101, a non-conductive working medium 103, and one or more gasbags 105, where the electronic device is immersed in the non-conductive working medium; the non-conductive working medium is configured to dissipate heat for the electronic device, and a volume of the non-conductive working medium expands as a temperature rises; and a surface of the gasbag is elastic, and the gasbag is configured to reduce its volume when the gasbag is compressed by volume expansion of the non-conductive working medium, so as to buffer a pressure rise in the system, where the pressure rise is caused by the volume expansion of the non-conductive working medium.

The heat source electronic device 101 is immersed in the non-conductive working medium, and the non-conductive working medium 103 fills up the inside of a case. Gasbags of different sizes and different shapes are placed in the non-conductive working medium.

The gasbag 105 is packed with a gas. The gasbag is generally made of a rubber material, and its surface has a certain compression or expansion capability. In a specific implementation instance of the present invention, the gasbag is applied in an immersion heat dissipation system to achieve a purpose of controlling pressure. The gasbag may adopt a gasbag that is commonly used in a municipal pipeline and a hydraulic system currently.

In essence, the gasbag can pack a gas, and part or all of surfaces of the gasbag can change according to a change of a difference between internal and external pressures, so that the gas in the gasbag can be compressed when the non-conductive working medium expands, and on the contrary, the gas in the gasbag can be expanded under the internal pressure when the volume of the non-conductive working medium is reduced. Referring to FIG. 2, FIG. 2 is a schematic diagram of a gasbag with only one movable surface 201. When a volume of the gas expands, the movable surface moves outward to increase the volume of the gas; and when the volume of the gas needs to be reduced, the movable surface moves inward to reduce the volume of the gas. In FIG. 2, (a) shows an initial state of the gasbag, (b) shows a gasbag state after the gas expands, and (c) shows a gasbag state after the gas is compressed.

If the gas in the gasbag is considered as an ideal gas in terms of engineering thermodynamics, the pressure of the gas in the gasbag complies with an ideal gas state equation in terms of engineering thermodynamics, as shown in formula (1):

VP=nRT (1)

where P represents the pressure of the gas, V represents the volume of the gas, T represents an absolute temperature of the gas, n represents the amount of substance of the ideal gas, and R represents a gas constant.

When the system works, after the non-conductive working medium absorbs heat generated by a heat source, a temperature of the non-conductive working medium increases and a volume of the non-conductive working medium expands, and the non-conductive working medium extrudes the gasbag. After the gasbag is compressed by the non-conductive working medium, due to compressibility of the gas, the gasbag reduces its volume, and meanwhile its internal pressure rises. When a balance is achieved, a decrease in volume of the gasbag is equal to an increase in volume of the non-conductive working medium after expansion. When the heat source generates less heat due to reduction of power consumption, causing that the temperature of the non-conductive working medium decreases, or when the temperature of the non-conductive working medium decreases and the volume of the non-conductive working medium is reduced due to other environmental factors, the volume of the gasbag increases and meanwhile the pressure in the gasbag decreases. When a balance is achieved, an increase in volume of the gasbag is equal to a decrease in volume of the non-conductive working medium.

That the gasbag reduces its volume when the gasbag is compressed by volume expansion of the non-conductive working medium includes: reducing, by the gasbag, its volume according to an ideal gas state equation, and calculating a reduced volume of the gasbag according to the following formula (2):

$${V}_{2} - {V}_{1} = nR ( \frac{{T}_{2}}{{P}_{2}} - \frac{{T}_{1}}{{P}_{1}} ) \qquad ( 2 )$$

where V₁ represents a volume of the gasbag before the volume of the gasbag is reduced, and V₂ represents a volume of the gasbag after the volume of the gasbag is reduced; T₁ represents an absolute temperature of the gas in the gasbag before the volume of the gasbag is reduced, and T₂ represents an absolute temperature of the gas in the gasbag after the volume of the gasbag is reduced; P₁ represents a pressure of the gas in the gasbag before the volume of the gasbag is reduced, and P₂ represents a pressure of the gas in the gasbag after the volume of the gasbag is reduced; n represents the amount of substance of the gas in the gasbag; and R represents a gas constant.

In this embodiment of the present invention, a working temperature of the non-conductive working medium in the immersion system is controlled within a certain range, that is, a temperature change of the gasbag falls within a certain range. If a volume V₂ after the volume of the gasbag is reduced or expanded and an initial volume V₁ of the gasbag are controlled within a certain range, the pressure in the gasbag is also controlled within a certain allowed range. Because a certain balance relationship exists between the pressure in the gasbag and the pressure of the non-conductive working medium in the immersion system, the pressure of the immersion system may be controlled through design of the gasbag.

The number of the one or more gasbags is determined according to a volume expansion value of the non-conductive working medium and a volume decrease value of each gasbag, which specifically includes calculating the number of the one or more gasbags according to formula (3):

$${\sum }_{i = 1}^{N} ∇ {v}_{i} \geq ∇ V \qquad ( 3 )$$

wherein ∇V represents the volume expansion value of the non-conductive working medium, and ∇vᵢ represents a volume decrease value of an i^{th} gasbag, wherein i is a natural number that is greater than or equal to 1 but less than or equal to N; and N is the number of the gasbags, and N needs to ensure that a sum of volume decrease values of all gasbags is greater than or equal to the volume expansion value of the non-conductive working medium.

The pressure of the immersion system can be controlled as long as a proper ratio of a total volume of the gasbags to an expansion volume of the non-conductive working medium is ensured. In this embodiment of the present invention, the shape and the number of gasbags may be flexibly set according to a specific condition in the case.

The gasbag adopted in this embodiment is a gasbag in a conventional industrial system, but in fact, the specific form of the gasbag may be varied and designed according to a specific condition of an immersion heat dissipation solution.

The gasbag is fixed at a position that is isolated from the electronic device 101 through the non-conductive working medium. By properly setting the position of the gasbag, such a design can avoid defects in an existing solution, such as defects that the electronic device is exposed in the gas and the air isolates heat exchange between the non-conductive working medium and the case, thereby further improving heat dissipation performance of the entire system.

In this embodiment of the present invention, the non-conductive working medium is a non-conductive liquid or non-conductive gas.

An embodiment of the present invention provides an immersion cooling method. Referring to FIG. 3, FIG. 3 is a flowchart of an immersion cooling method according to an embodiment of the present invention. The method includes:

S301: Dissipate heat for an electronic device by using a non-conductive working medium.

S1303: A gasbag reduces its volume when the gasbag is compressed by volume expansion of the non-conductive working medium, so as to buffer a pressure rise in a system, where the pressure rise is caused by the volume expansion of the non-conductive working medium.

The system includes the electronic device, the non-conductive working medium, and one or more gasbags.

That a gasbag reduces its volume when the gasbag is compressed by volume expansion of the non-conductive working medium includes: calculating a reduced volume of the gasbag according to formula (4):

$${V}_{2} - {V}_{1} = nR ( \frac{{T}_{2}}{{P}_{2}} - \frac{{T}_{1}}{{P}_{1}} ) \qquad ( 4 )$$

where V₁ represents a volume of the gasbag before the volume of the gasbag is reduced, and V₂ represents a volume of the gasbag after the volume of the gasbag is reduced; T₁ represents an absolute temperature of a gas in the gasbag before the volume of the gasbag is reduced, and T₂ represents an absolute temperature of the gas in the gasbag after the volume of the gasbag is reduced; P₁ represents a pressure of the gas in the gasbag before the volume of the gasbag is reduced, and P₂ represents a pressure of the gas in the gasbag after the volume of the gasbag is reduced; n represents the amount of substance of the gas in the gasbag; and R represents a gas constant.

The number of the one or more gasbags is determined according to a volume expansion value of the non-conductive working medium and a volume decrease value of each gasbag.

That the number of the one or more gasbags is determined according to the volume expansion value of the non-conductive working medium and the volume decrease value of each gasbag specifically includes determining the number of the one or more gasbags according to formula (5):

$${\sum }_{i = 1}^{N} ∇ {v}_{i} \geq ∇ V \qquad ( 5 )$$

wherein ∇V represents the volume expansion value of the non-conductive working medium, and ∇vᵢ represents a volume decrease value of an i^{th} gasbag, wherein i is a natural number that is greater than or equal to 1 but less than or equal to N; and N is the number of the gasbags, and N needs to ensure that a sum of volume decrease values of all gasbags is greater than or equal to the volume expansion value of the non-conductive working medium.

Persons skilled in the art may understand that an accompanying drawing is only a schematic diagram of an exemplary embodiment, and modules or procedures in the accompanying drawing are not necessarily required for implementing the present invention.

Finally, it should be noted that the foregoing embodiments are only intended for describing the technical solutions of the present invention rather than limiting the present invention. Although the present invention is described in detail with reference to the foregoing embodiments, persons of ordinary skill in the art should understand that they may still make modifications to the technical solutions described in the foregoing embodiments or make equivalent replacements to some technical features of the technical solutions, as long as these modifications or replacements do not make the essence of corresponding technical solutions depart from the spirit and scope of the technical solutions in the embodiments of the present invention.

What is claimed is:

1. An immersion cooling system, comprising:
an electronic device immersed in a non-conductive working medium, and one or more gasbags;
wherein the non-conductive working medium is configured to dissipate heat for the electronic device, and a volume of the non-conductive working medium expands as a temperature rises; and
wherein a surface of the gasbag is elastic, and the gasbag is configured to reduce its volume when the gasbag is compressed by volume expansion of the non-conductive working medium, so as to buffer a pressure rise in the system, wherein the pressure rise is caused by the volume expansion of the non-conductive working medium.

2. The system according to claim 1, wherein a reduced volume of the gasbag is calculated according to the following formula:
$${V}_{2} - {V}_{1} = nR ( \frac{{T}_{2}}{{P}_{2}} - \frac{{T}_{1}}{{P}_{1}} ) ,$$
wherein V₁ represents a volume of the gasbag before the volume of the gasbag is reduced, and V₂ represents a volume of the gasbag after the volume of the gasbag is reduced; T₁ represents an absolute temperature of a gas in the gasbag before the volume of the gasbag is reduced, and T₂ represents an absolute temperature of the gas in the gasbag after the volume of the gasbag is reduced; P₁ represents a pressure of the gas in the gasbag before the volume of the gasbag is reduced, and P₂ represents a pressure of the gas in the gasbag after the volume of the gasbag is reduced; n represents the amount of substance of the gas in the gasbag; and R represents a gas constant.

3. The system according to claim 1, wherein:
a number of the one or more gasbags is determined according to a volume expansion value of the non-conductive working medium and a volume decrease value of each gasbag.

4. The system according to claim 3, wherein the number of the one or more gasbags is determined according to the following formula:
$${\sum }_{i = 1}^{N} ∇ {v}_{i} \geq ∇ V ,$$
wherein ∇V represents the volume expansion value of the non-conductive working medium, and ∇vᵢ represents a volume decrease value of an i^{th} gasbag, wherein i is a natural number that is greater than or equal to 1 but less than or equal to N; and N is the number of the gasbags, and N needs to ensure that a sum of volume decrease values of all gasbags is greater than or equal to the volume expansion value of the non-conductive working medium.

5. The system according to claim 1, wherein:
the gasbag is fixed at a position that is isolated from the electronic device through the non-conductive working medium.

6. The system according to claim 1, wherein:
the non-conductive working medium is a non-conductive liquid or non-conductive gas.

7. An immersion cooling method, wherein the method comprises:
dissipating heat for an electronic device by using a non-conductive working medium in a closed container, wherein the electronic device is immersed in the non-conductive working medium, and placing one or more gasbags in the non-conductive working medium; and
reducing, by the gasbag, its volume when the gasbag is compressed by volume expansion of the non-conductive working medium, so as to buffer a pressure rise in a system, wherein the volume expansion of the non-conductive working medium is caused by dissipating heat for the electronic device and the pressure rise is caused by the volume expansion of the non-conductive working medium.

8. The method according to claim 7, wherein a reduced volume of the gasbag is determined according to the following formula:
$${V}_{2} - {V}_{1} = nR ( \frac{{T}_{2}}{{P}_{2}} - \frac{{T}_{1}}{{P}_{1}} ) ,$$
wherein V₁ represents a volume of the gasbag before the volume of the gasbag is reduced, and V₂ represents a volume of the gasbag after the volume of the gasbag is reduced; T₁ represents an absolute temperature of a gas in the gasbag before the volume of the gasbag is reduced, and T₂ represents an absolute temperature of the gas in the gasbag after the volume of the gasbag is reduced; P₁ represents a pressure of the gas in the gasbag before the volume of the gasbag is reduced, and P₂ represents a pressure of the gas in the gasbag after the volume of the gasbag is reduced; n represents the amount of substance of the gas in the gasbag; and R represents a gas constant.

9. The method according to claim 7, wherein:
placing one or more gasbags in the non-conductive working medium comprises: determining the number of the one or more gasbags according to a volume expansion value of the non-conductive working medium and a volume decrease value of each gasbag.

10. The method according to claim 9, wherein:
determining the number of the one or more gasbags according to a volume expansion value of the non-conductive working medium and a volume decrease value of each gasbag comprises: determining the number of the one or more gasbags according to the following formula:
$${\sum }_{i = 1}^{N} ∇ {v}_{i} \geq ∇ V ,$$
wherein ∇V represents the volume expansion value of the non-conductive working medium, and ∇vᵢ represents a volume decrease value of an i^{th} gasbag, wherein i is a natural number that is greater than or equal to 1 but less than or equal to N; and N is the number of the gasbags, and N needs to ensure that a sum of volume decrease values of all gasbags is greater than or equal to the volume expansion value of the non-conductive working medium.

11. The method according to claim 7, wherein:
the non-conductive working medium is a non-conductive liquid or non-conductive gas.
